(19) United States
(12) Patent Application Publication
(10) Pub. No.: US 2025/0070777 A1
(43) Pub. Date: Feb. 27, 2025

(54) PULSE TRANSMISSION CIRCUIT, SIGNAL TRANSMISSION DEVICE, AND ELECTRONIC APPARATUS

(71) Applicant: ROHM CO., LTD., Kyoto (JP)

(72) Inventor: Shingo HASHIGUCHI, Kyoto (JP)

(21) Appl. No.: 18/939,120

(22) Filed: Nov. 6, 2024

Related U.S. Application Data
(63) Continuation of application No. PCT/JP2023/012465, filed on Mar. 28, 2023.

(30) Foreign Application Priority Data
May 30, 2022 (JP) 2022-087735

(51) Int. Cl. H03K 17/689; H03M 1/78

(52) U.S. Cl. CPC H03K 17/689; H03M 1/785

(57) ABSTRACT

A pulse transmission circuit is incorporated in a signal transmission device employing a capacitive insulation method, and configured to cause a transmission pulse signal, which is transmitted to a capacitor of a subsequent stage, to make a gradual logic-level transition when a logic level of an input pulse signal switches. For example, the pulse transmission circuit may be configured to trigger the transmission pulse signal a plurality of times, while causing the transmission pulse signal to make a gradual logic-level transition, so as to repeat raising and lowering of the transmission pulse signal.

### CROSS-REFERENCE TO RELATED APPLICATIONS

This nonprovisional application is a continuation application of International Patent Application No. PCT/JP2023/012465 filed on Mar. 28, 2023, which claims priority Japanese Patent Application No. 2022-087735 filed on May 30, 2022, the entire contents of which are hereby incorporated by reference.

### TECHNICAL FIELD

The present disclosure relates to a pulse transmission circuit, a signal transmission device, and an electronic apparatus.

### BACKGROUND ART

A signal transmission device employing a capacitive insulation method is known as means for transmitting a pulse signal between a primary circuit system and a secondary circuit system while insulating the primary circuit system and the secondary circuit system from each other.

An example of conventional technologies related to the above is disclosed in Patent Document 1 identified below.

### CITATION LIST

### Patent Literature

Patent Document 1: JP-A-2014-176045

### BRIEF DESCRIPTION OF DRAWINGS

FIG. 1 is a diagram illustrating a signal transmission device employing a magnetic isolation method.

FIG. 2 is a diagram illustrating a signal transmission device employing a capacitive isolation method.

FIG. 3 is a diagram illustrating an example of an electronic apparatus including a signal transmission device.

FIG. 4 is a diagram illustrating how a signal amplitude attenuates between input and output nodes.

FIG. 5 is a diagram illustrating how a potential change propagates between substrate nodes.

FIG. 6 is a diagram illustrating verification patterns for common mode transient immunity.

FIG. 7 is a diagram illustrating a first embodiment that enhances common mode transient immunity.

FIG. 8 is a diagram for illustrating signal decomposition of common mode noise.

FIG. 9 is a diagram illustrating a second embodiment that enhances common mode transient immunity.

FIG. 10 is a diagram illustrating a third embodiment that enhances common mode transient immunity.

FIG. 11 is a diagram illustrating a configuration example of a pulse transmission circuit.

FIG. 12 is a diagram illustrating a configuration example of a DAC.

FIG. 13 is a diagram illustrating relationship between selection states of selectors and DAC output values.

FIG. 14 is a diagram illustrating an example of a reception pulse signal.

### DESCRIPTION OF EMBODIMENTS

### Signal Transmission Device (Magnetic Insulation Method)

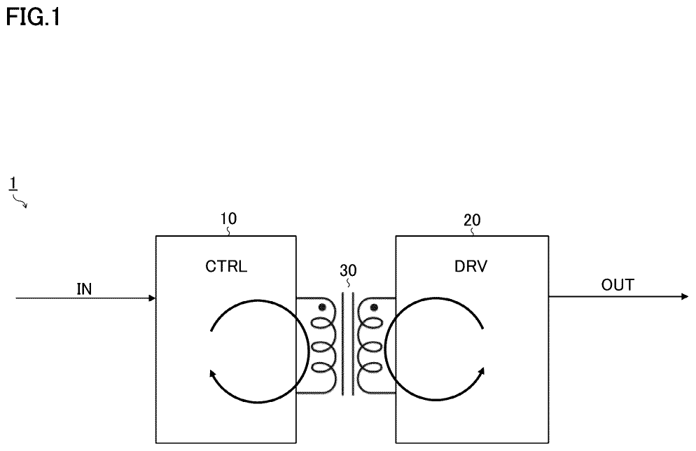

FIG. 1 is a diagram illustrating a signal transmission device employing a magnetic insulation method. A signal transmission device 1 of the present figure is a semiconductor integrated circuit device (specifically, an insulating gate driver IC) that transmits a pulse signal between a primary circuit system and a secondary circuit system while electrically separating the primary circuit system and the secondary circuit system from each other by way of magnetic coupling.

As illustrated in the present figure, the signal transmission device 1 includes a controller chip 10, a driver chip 20, and a transformer 30.

The controller chip 10, which is disposed in the primary circuit system, converts an input pulse signal IN (e.g., a PWM (pulse width modulation) signal) into a transmission pulse signal, and in accordance with the transmission pulse signal, controls a primary current flowing through a primary coil of the transformer 30. That is, in the controller chip 10, a primary current loop exists.

The driver chip 20, which is disposed in the secondary circuit system, generates a reception pulse signal in accordance with a secondary current flowing through a secondary coil of the transformer 30, converts the reception pulse signal into an output pulse signal OUT, and outputs the output pulse signal OUT to a load (e.g., a power transistor). That is, in the driver chip 20, a secondary current loop exists.

The transformer 30, which is disposed between the primary circuit system and the secondary circuit system, transmits a change of the primary current flowing through the primary coil as a change of the secondary current flowing through the secondary coil. That is, the transformer 30 converts a current signal (=the primary current) of the primary circuit system into magnetic energy and then transmits it as a current signal (=the secondary current) of the secondary circuit system.

Note that the signal transmission device 1 employing the magnetic insulation method is excellent in common mode transient immunity (CMTI that is one of important characteristics. However, it is costly due to the need for the transformer 30.

### Signal Transmission Device (Capacitive Insulation Method)

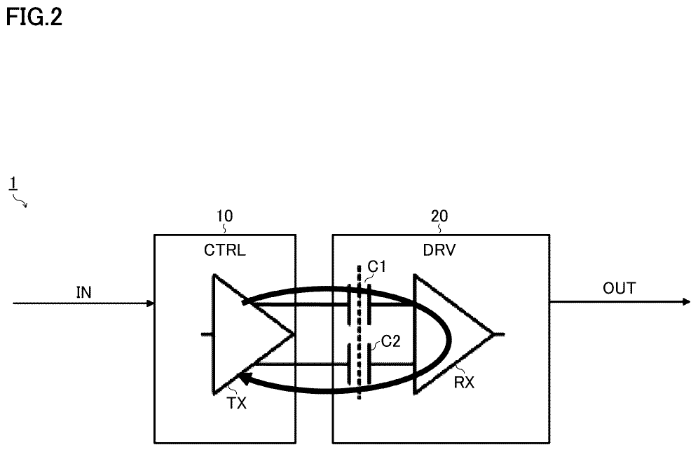

FIG. 2 is a diagram illustrating a signal transmission device employing a capacitive insulation method. A signal transmission device 1 of the present figure is a semiconductor integrated circuit device (specifically, an insulating gate driver IC) that transmits a pulse signal between a primary circuit system and a secondary circuit system while electrically separating the primary circuit system and the secondary circuit system from each other by way of capacitive coupling.

As illustrated in the present figure, the signal transmission device 1 includes a pulse transmission circuit TX, a pulse reception circuit RX, and capacitors C1 and C2.

The pulse transmission circuit TX, which is disposed in the primary circuit system, generates a transmission pulse signal corresponding to the input pulse signal IN, and outputs the transmission pulse signal to the capacitors C1 and C2. The pulse transmission circuit TX may be integrated in the controller chip 10.

The capacitors C1 and C2, which are disposed between the primary circuit system and the secondary circuit system, receive the transmission pulse signal output by the pulse transmission circuit TX, and transmit a reception pulse signal corresponding to the transmission pulse signal to the pulse reception circuit RX. In this manner, by way of the capacitors C1 and C2, without direct transmission and reception of electric signals, signal transmission is achieved as a transient current change. That is, a current loop is formed astride the controller chip 10 and the driver chip 20.

Note that the capacitors C1 and C2 may both be integrated in the driver chip 20. The capacitors C1 and C2 can generally be formed inexpensively using a metal conductor (e.g., an aluminum conductor).

The pulse reception circuit RX, which is disposed in the secondary circuit system, outputs the output pulse signal OUT corresponding to the reception pulse signal transmitted via the capacitors C1 and C2. The pulse reception circuit RX may be integrated in the driver chip 20.

Note that the signal transmission device 1 employing the capacitive insulation method has not only excellent EMC (electro-magnetic compatibility) and EMI (electro-magnetic interference) characteristics, which are among the important characteristics, but also high responsivity. Thus, it can be said that the signal transmission device 1 employing the capacitive insulation method is suitable in, for example, an application where high-speed driving of a GaN device is required.

### Electronic Apparatus

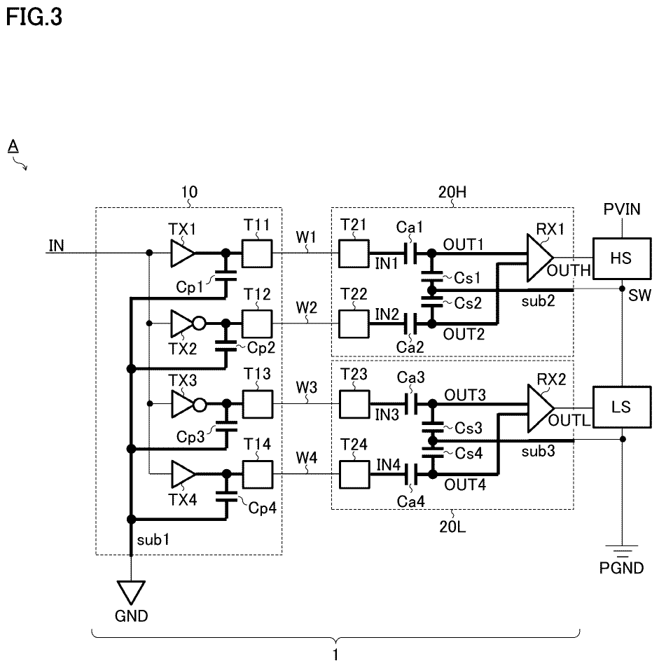

FIG. 3 is a diagram illustrating an example of an electronic apparatus including a signal transmission device employing a capacitive insulation method. An electronic apparatus A of the present configuration example includes a signal transmission device 1, and a high-side switch HS and a low-side switch LS.

The signal transmission device 1, as in the previously referenced FIG. 2, transmits a pulse signal between the primary circuit system and the secondary circuit system while electrically separating the primary circuit system and the secondary circuit system from each other by way of capacitive coupling. Note that the signal transmission device 1 may be, for example, a semiconductor integrated circuit device where a controller chip 10 (=equivalent to a first chip), in which mainly a circuit element of the primary circuit system is integrated, and driver chips 20H and 20L (=each equivalent to a second chip), in which a circuit element of the secondary circuit system is integrated, are sealed in a single package.

As illustrated in the present figure, the signal transmission device 1 includes pulse transmission circuits TX1 to TX4, pulse reception circuits RX1 and RX2, and capacitors Ca1 to Ca4.

The pulse transmission circuits TX1 to TX4, which are all disposed in the primary circuit system, generate transmission pulse signals IN1 to IN4 corresponding to the input pulse signal IN. The pulse transmission circuits TX1 to TX4 may all be integrated in the controller chip 10.

An input end of the pulse transmission circuit TX1 is connected to an application end of the input pulse signal IN. An output end of the pulse transmission circuit TX1 is connected to a pad T11 of the controller chip 10. The pulse transmission circuit TX1 may be a buffer. Note that, between the pad T11 of the controller chip 10 and a substrate node sub1 (=an application end of a ground voltage GND), a pad capacitance Cp1 is associated.

An input end of the pulse transmission circuit TX2 is connected to the application end of the input pulse signal IN. An output end of the pulse transmission circuit TX2 is connected to a pad T12 of the controller chip 10. The pulse transmission circuit TX2 may be an inverter. Note that, between the pad T12 of the controller chip 10 and the substrate node sub1, a pad capacitance Cp2 is associated.

An input end of the pulse transmission circuit TX3 is connected to the application end of the input pulse signal IN. An output end of the pulse transmission circuit TX3 is connected to a pad T13 of the controller chip 10. The pulse transmission circuit TX3 may be an inverter. Note that, between the pad T13 of the controller chip 10 and the substrate node sub1, a pad capacitance Cp3 is associated.

An input end of the pulse transmission circuit TX4 is connected to the application end of the input pulse signal IN. An output end of the pulse transmission circuit TX4 is connected to a pad T14 of the controller chip 10. The pulse transmission circuit TX4 may be a buffer. Note that, between the pad T14 of the controller chip 10 and the substrate node sub1, a pad capacitance Cp4 is associated.

The capacitors Ca1 and Ca2, which are both disposed between the primary circuit system and the secondary circuit system, respectively receive transmission pulse signals IN1 and IN2, which are respectively output from the pulse transmission circuits TX1 and TX2, and respectively transmit reception pulse signals OUT1 and OUT2, which respectively correspond to the transmission pulse signals IN1 and IN2, to the pulse reception circuit RX1. Note that the capacitors Ca1 and Ca2 may both be integrated in the driver chip 20H.

A first end of the capacitor Ca1 is connected to a pad T21 (=an application end of the transmission pulse signal IN1) of the driver chip 20H. Between the pad T11 of the controller chip 10 and the pad T21 of the driver chip 20H, bonding is established via a wire W1. A second end of the capacitor Ca1 (=an application end of the reception pulse signal OUT1) is connected to a first differential input end of the pulse reception circuit RX1. Note that, between the second end of the capacitor Ca1 and a substrate node sub2 (=an application end of a switch voltage SW) of the driver chip 20H, a to-substrate capacitance Cs1 is associated.

A first end of the capacitor Ca2 is connected to a pad T22 (=an application end of the transmission pulse signal IN2) of the driver chip 20H. Between the pad T12 of the controller chip 10 and the pad T22 of the drive chip 20H, bonding is established via a wire W2. A second end of the capacitor Ca2 (=an application end of the reception pulse signal OUT2) is connected to a second differential input end of the pulse reception circuit RX1. Note that, between the second end of the capacitor Ca2 and the substrate node sub2 of the driver chip 20H, a to-substrate capacitance Cs2 is associated.

The capacitors Ca3 and Ca4, which are both disposed between the primary circuit system and the secondary circuit system, receive transmission pulse signals IN3 and IN4, which are respectively output from the pulse transmission circuits TX3 and TX4, and transmit reception pulse signals OUT3 and OUT4 corresponding to the transmission pulse signals IN3 and IN4 to the pulse reception circuit RX2. Note that the capacitors Ca3 and Ca4 may both be integrated in the driver chip 20L.

A first end of the capacitor Ca3 is connected to a pad T23 (=an application end of the transmission pulse signal IN3) of the driver chip 20L. Between the pad T13 of the controller chip 10 and the pad T23 of the drive chip 20L, bonding is established via a wire W3. A second end of the capacitor Ca3 (=an application end of the reception pulse signal OUT3) is connected to a first differential input end of the pulse reception circuit RX2. Note that, between the second end of the capacitor Ca3 and a substrate node sub3 (=an application end of a ground voltage PGND) of the driver chip 20L, a to-substrate capacitance Cs3 is associated.

A first end of the capacitor Ca4 is connected to a pad T24 (=an application end of the transmission pulse signal IN4) of the driver chip 20L. Between the pad T14 of the controller chip 10 and the pad T24 of the drive chip 20L, bonding is established via a wire W4. A second end of the capacitor Ca4 (=an application end of the reception pulse signal OUT4) is connected to a second differential input end of the pulse reception circuit RX2. Note that, between the second end of the capacitor Ca4 and the substrate node sub3 of the driver chip 20L, a to-substrate capacitance Cs4 is associated.

The capacitors Ca1 to Ca4 described above can generally be formed inexpensively using a metal conductor (e.g., an aluminum conductor).

In this manner, by way of the capacitors Ca1 to Ca4, without direct reception and transmission of electric signals, signal transmission is achieved as a transient current change. That is, in the signal transmission device 1, current loops are formed one astride the controller chip 10 and the driver chip 20H and another astride the controller chip 10 and the driver chip 20L.

The pulse reception circuit RX, which is disposed in the secondary circuit system, outputs an output pulse signal OUTH corresponding to the reception pulse signals OUT1 and OUT2 transmitted via the capacitors Ca1 and Ca2. The pulse reception circuit RX1 may be integrated in the driver chip 20H.

The pulse reception circuit RX2, which is disposed in the secondary circuit system, outputs an output pulse signal OUTL corresponding to the reception pulse signals OUT3 and OUT4 transmitted via the capacitors Ca3 and Ca4. The pulse reception circuit RX2 may be integrated in the driver chip 20L.

The high-side switch HS and the low-side switch LS are connected in series between a power system power supply end (=an application end of a power supply voltage PVIN) and a power system ground end (=the application end of the ground voltage PGND), and are complementarily turned on/off in accordance with the output pulse signals OUTH and OUTL output from the signal transmission device 1. That is, as seen from the signal transmission device 1, the high-side switch HS and the low-side switch LS is equivalent to a load (=a drive target) to be turned on/off in response to the output pulse signals OUTH and OUTL.

Note that the switch voltage SW, which is output from a connection node of the high-side switch HS and the low-side switch LS, is a rectangular wave signal that is pulse-driven between the power supply voltage PVIN and the ground voltage PGND. A half-bridge output stage that generates this switch voltage SW can be used as the output stage of a switching power supply or a motor drive device, for example.

### Discussion on Common Mode Transient Immunity (CMTI)

To enhance the common mode transient immunity (CMTI) of the signal transmission device 1 employing the capacitive insulation method, it is necessary to give consideration to signal amplitudes between the input and output nodes and between the substrate nodes.

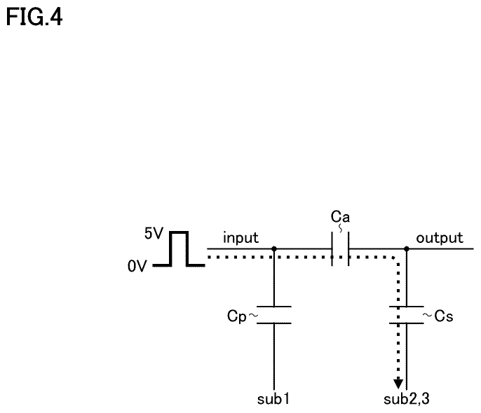

FIG. 4 is a diagram illustrating how a signal amplitude attenuates between the input and output nodes. Note that a pad capacitance Cp, a capacitor Ca, and a to-substrate capacitance Cs in the figure are respectively equivalent to the pad capacitances Cp1 to Cp4, the capacitors Ca1 to Ca4, and the to-substrate capacitances Cs1 to Cs4 in FIG. 3. Further, an input node input and an output node output are respectively equivalent to the application ends of the transmission pulse signals IN1 to IN4 and the application ends of the reception pulse signals OUT1 to OUT4 in FIG. 3.

When the transmission pulse signal applied to the input node input is raised from low level (e.g., 0 V) to high level (e.g., 5 V), a current flows through a path from the input node input via the capacitor Ca and the to-substrate capacitance Cs to the substrate node sub2 or sub3 (see the dotted-line arrow in the figure). Accordingly, the reception pulse signal applied to the output node output is a signal obtained through capacitive division of the transmission pulse signal. Thus, a logic determination threshold for the reception pulse signal needs to be set to low level (e.g., 0.425 V), and this causes the reception pulse signal to be liable to be affected by common mode noise, which will be described later.

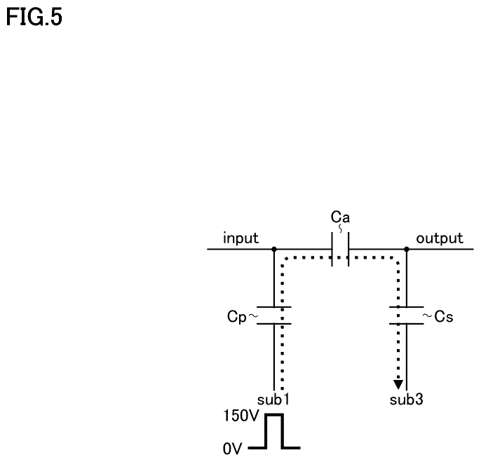

FIG. 5 is a diagram illustrating how a potential change propagates between the substrate nodes. For example, in a CMTI test to which the signal transmission device 1 is subjected, a potential change (e.g., up to 150 V/ns) generated at the substrate node sub1 (=GND) of the primary circuit system propagates around the substrate node sub3 (=PGND) of the secondary circuit system. This necessitates countermeasures to prevent erroneous detection of the reception pulse signal.

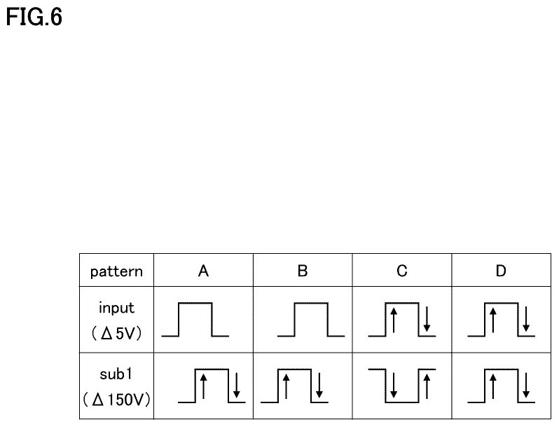

FIG. 6 is a diagram illustrating verification patterns for common mode transient immunity (CMTI). A top row of the present figure depicts transmission pulse signals (=equivalent to the transmission pulse signals IN1 to IN4 in FIG. 3) applied to the input node input. A bottom row of the present figure depicts potential changes (so-called common mode noise) generated in the substrate node sub1.

In the signal transmission device 1 employing the capacitive insulation method, as a trigger for switching the logic level of the output pulse signal OUTH (or OUTL), a pulse edge of the transmission pulse signal applied to the input node input (and thus a pulse edge of the reception pulse signal applied to the output node output) in FIG. 4 or FIG. 5 is detected. Thus, in order to verify the common mode transient immunity (CMTI), it is necessary to verify patterns A to D illustrated in the present figure.

Pattern A represents a case where the potential of the substrate node sub1 changes when the potential of the input node input is stable. In the present figure, during a period when the input node input is at high level (5 V), the potential of the substrate node sub1 rises from low level (0 V) to high level (150 V), and during a period when the input node input is at low level (0 V), the substrate node sub1 falls from high level (150 V) to low level (0 V). In this case, there is no obstacle to trigger detection.

Pattern B, as the above-described pattern A, represents a case where the potential of the substrate node sub1 changes when the potential of the input node input is stable. In the present figure, during a period when the input node input is at low level (0 V), the potential of the substrate node sub1 rises from low level (0 V) to high level (150 V), and during a period when the input node input is at high level (5 V), the substrate node sub1 falls from high level (150 V) to low level (0 V). In this case, there is no obstacle to trigger detection. In this point, pattern A is similar to pattern A described previously.

Pattern C represents a case where a potential change of the input node input and a potential change of the substrate node sub1 occur simultaneously. In the present figure, at a timing when the input node input rises from low level (0 V) to high level (5 V), the substrate node sub1 falls from high level (150 V) to low level (0 V), and at a timing when the input node input falls from high level (5 V) to low level (0 V), the substrate node sub1 rises from low level (0 V) to high level (150 V). In this case, a pulse edge of the reception pulse signal applied to the output node output is drowned out by common mode noise, and thus there may be generated an obstacle to trigger detection.

Pattern D, as the above-described pattern C, represents a case where a potential change of the input node input and a potential change of the substrate node sub1 occur simultaneously. In the present figure, at a timing when the input node input rises from low level (0 V) to high level (5 V), the substrate node sub1 rises from low level (0 V) to high level (150 V), and at a timing when the input node input falls from high level (5 V) to low level (0 V), the substrate node sub1 falls from high level (150 V) to low level (0 V). In this case, a pulse edge of the reception pulse signal applied to the output node output is buried in common mode noise, and thus there may be generated an obstacle to trigger detection.

In what follows, in view of the above verification, a proposal will be made as to new amendments (examples of CMTI countermeasures) for enhancing common mode transient immunity (CMTI).

### First Embodiment

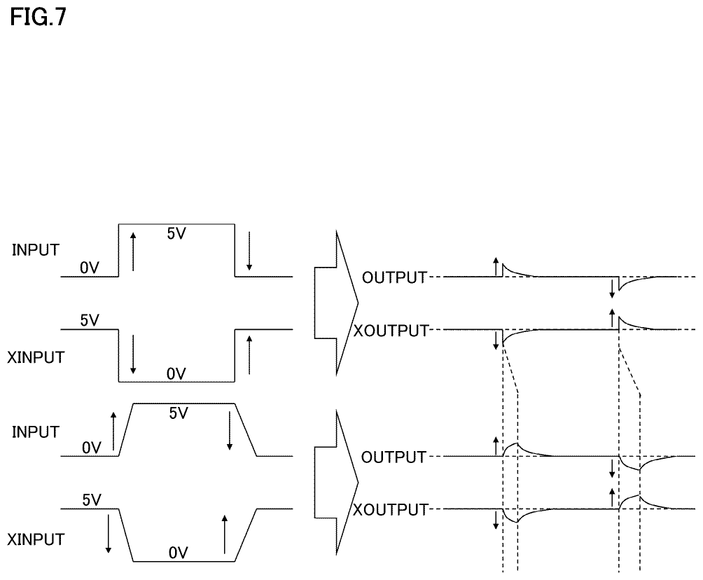

FIG. 7 is a diagram illustrating a first embodiment for enhancing common mode transient immunity (CMTI). Note that, a top row (left side) of the present figure depicts a transmission pulse signal INPUT and an inverted transmission pulse signal XINPUT, which are without countermeasures, and the top row (right side) of the present figure depicts a reception pulse signal OUTPUT and an inverted reception pulse signal XOUTPUT, which are without countermeasures. Further, a bottom row (left side) of the present figure depicts a transmission pulse signal INPUT and an inverted transmission pulse signal XINPUT of the first embodiment are depicted, and the bottom row (right side) of the present figure depicts a reception pulse signal OUTPUT and an inverted reception pulse signal XOUTPUT of the first embodiment.

The transmission pulse signal INPUT is equivalent to the transmission pulse signal IN1 or IN3 in FIG. 3. The inverted transmission pulse signal XINPUT is equivalent to the transmission pulse signal IN2 or IN4 in FIG. 3.

The reception pulse signal OUTPUT is equivalent to the reception pulse signal OUT1 or OUT3 in FIG. 3. The inverted reception pulse signal XOUTPUT is equivalent to the reception pulse signal OUT2 or OUT4 in FIG. 3.

In the signal transmission device 1 employing the capacitive insulation method, it is necessary to detect pulse edges of the transmission pulse signal INPUT and the inverted transmission pulse signal XINPUT and thus pulse edges of the reception pulse signal OUTPUT and the inverted reception pulse signal XOUTPUT.

However, as illustrated in the top row of the present figure, when the logic level of each of the transmission pulse signal INPUT and the inverted transmission pulse signal XINPUT is switched abruptly, a period during which the pulse edge of each of the reception pulse signal OUTPUT and the inverted reception pulse signal XOUTPUT can be detected (=trigger pulse width) becomes extremely short.

Due to this, if the reception pulse signal OUTPUT and the inverted reception pulse signal XOUTPUT become superimposed with common mode noise at a timing when a pulse edge is generated in each of them, the pulse edge of each of the reception pulse signal OUTPUT and the inverted reception pulse signal XOUTPUT is drowned out by, or buried in, the common mode noise, and thus there may be generated an obstacle to trigger detection.

To prevent this, in the first embodiment, as illustrated in the bottom row of the present figure, the transmission pulse signal INPUT and the inverted transmission pulse signal XINPUT are caused to make a gradual logic-level transition.

When this is adapted to the previously referenced FIG. 3, it is preferable that, when the logic level of the input pulse signal IN switches, the pulse transmission circuits TX1 to TX4 respectively cause the transmission pulse signals IN1 to IN4, which are respectively transmitted to the capacitors Ca1 to Ca4 of a subsequent stage, to make a gradual logic-level transition.

If the first embodiment is adopted, a pulse edge of each of the reception pulse signal OUTPUT and the inverted reception pulse signal XOUTPUT can be detected during a longer period (=the trigger pulse width becomes thicker). Thus, it becomes less likely that an erroneous operation of trigger detection occurs due to a common mode noise.

Not that, the first embodiment can be implemented easily by, for example, inserting a resistor into the output terminal of each of the pulse transmission circuits TX1 to TX4 and setting a large time constant t.

However, even in a case where the first embodiment is adopted, a potential change caused by one trigger in each of the reception pulse signal OUTPUT and the inverted reception pulse signal XOUTPUT is completely the same as in conventional cases. Thus, in a case where common mode noise gradually rises taking the same transition time as the transmission pulse signal INPUT and the inverted transmission pulse signal XINPUT, whichever with a larger potential change becomes predominant. Thus, as described previously, a pulse edge of each of the reception pulse signal OUTPUT and the inverted reception pulse signal XOUTPUT is drowned out by, or buried in, common mode noise, and thus an obstacle to trigger detection may be generated.

That is, merely by causing the transmission pulse signal INPUT and the inverted transmission pulse signal XINPUT to make a gradual logic-level transition, it is difficult to deal with various signal patterns of common mode noise. To overcome such a probabilistic reasoning, further consideration is needed.

### Signal Decomposition of Common Mode Noise

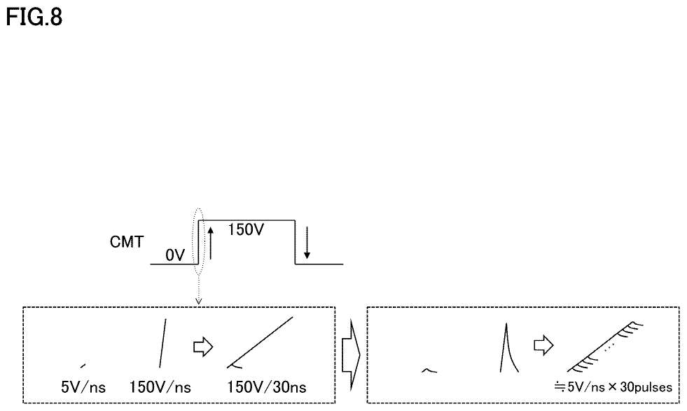

FIG. 8 is a diagram for illustrating signal decomposition of common mode noise CMT. The following description is based on the assumption that, in the present figure, while the potential change of the transmission pulse signal INPUT by one trigger is 5 V/ns, the potential change of common mode noise CMT is up to 150 V/ns (=a maximum spec value to be cleared).

For example, consider a case where the common mode noise CMT rises gradually, and its potential change is 15V/30 ns. In this case, the potential change with respect to 1 ns is 5 V/ns, which is equal to the potential change of the transmission pulse signal INPUT by one trigger.

Further, consider a case where the common mode noise CMT rises even more gradually, and its potential change is 150V/75 ns. In this case, the potential change with respect to 1 ns is 2 V/ns, which is smaller than the potential change of the transmission pulse signal INPUT by one trigger.

In view of this, it is clear that, by triggering the transmission pulse signal INPUT a plurality of times (5 V/ns×30 times in the present figure) over a period of 30 ns or longer (desirably, 40 ns to 90 ns), at least one of the pulse edges triggered a plurality of times can be detected correctly, whether the potential change of the common mode noise CMT is abrupt or gradual.

Hereinafter, a detailed description will be given of the above-mentioned operation by exemplifying specific embodiments.

### Second Embodiment

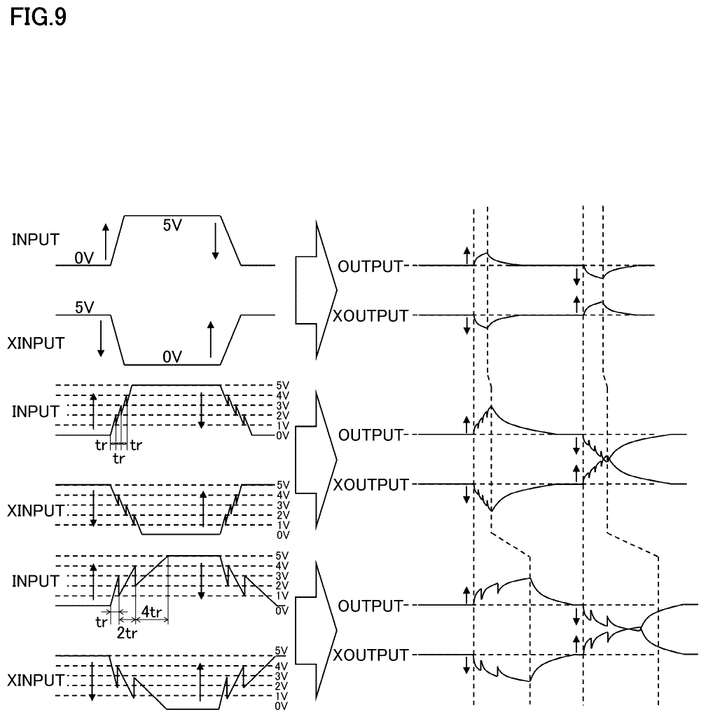

FIG. 9 is a diagram illustrating a second embodiment for enhancing common mode transient immunity (CMTI). Note that, a top row (left side) of the present figure depicts the transmission pulse signal INPUT and the inverted transmission pulse signal XINPUT of the first embodiment (the bottom row in FIG. 7), which have been described previously, and the top row (right side) of the present figure depicts the reception pulse signal OUTPUT and the inverted reception pulse signal XOUTPUT of the first embodiment. Further, middle and bottom rows (left side) of the present figure each depict a transmission pulse signal INPUT and an inverted transmission pulse signal XINPUT of the second embodiment, and the middle and bottom rows (right side) of the present figure each depict a reception pulse signal OUTPUT and an inverted reception pulse signal XOUTPUT of the second embodiment.

In the second embodiment, as illustrated in the middle and bottom rows of the present figure, during a gradual logic-level transition of each of the transmission pulse signal INPUT and the inverted transmission pulse signal XINPUT, the transmission pulse signal INPUT and the inverted transmission pulse signal XINPUT are each triggered a plurality of times such that the transmission pulse signal INPUT and the inverted transmission pulse signal XINPUT are each repeatedly raised and lowered.

That is, on-off-keying (OOK) of the transmission pulse signal INPUT and the inverted transmission pulse signal XINPUT is performed. According to this operation, trigger detection is performed at a plurality of timings. This enables more secure transmission of the transmission pulse signal INPUT and the inverted transmission pulse signal XINPUT each to a subsequent stage.

Further, by triggering each of the transmission pulse signal INPUT and the inverted transmission pulse signal XINPUT a plurality of times over a predetermined period (e.g., 30 ns or longer), it becomes less likely for a potential change of the common mode noise CMT, whether it is abrupt or gradual, to generate an obstacle to trigger detection. Thus, it becomes possible to enhance common mode transient immunity (CMTI).

Note that, when raising the transmission pulse signal INPUT and the inverted transmission pulse signal XINPUT each from low level (0 V) to high level (5 V), a lowering amount by each trigger may be set to be equal to or less than a raising amount. Further, when lowering the transmission pulse signal INPUT and the inverted transmission pulse signal XINPUT each from high level (5 V) to low level (0 V), a raising amount by each trigger may be set to be equal to or less than a lowering amount.

Referring to the transmission pulse signal INPUT in the middle row of the present figure, when raised from low level (0 V) to high level (5 V), while the raising amount by each trigger is +2 V, the lowering amount by each trigger is set to −1 V. Accordingly, the transmission pulse signal INPUT, while repeating potential change of rising by 2 V and falling by 1 V with respect to each trigger, eventually makes a transition from low level (0 V) to high level (5 V) by four triggers.

On the other hand, when lowered from high level (5 V) to low level (0 V), while the raising amount by each trigger is +1 V, the lowering amount by each trigger is set to −2 V. Accordingly, the transmission pulse signal INPUT, while repeating potential change of falling by 2 V and rising by 1 V with respect to each trigger, eventually makes a transition from high level (5 V) to low level (0 V) by four triggers.

According to this setting, potential changes of each of the reception pulse signal OUTPUT and the inverted reception pulse signal XOUTPUT accumulate. This makes it possible to enhance the level of trigger detection in a pseudo manner.

Referring to the transmission pulse signal INPUT in the bottom row of the present figure, when raised from low level (0 V) to high level (5 V), while the raising amount by each trigger is +3 V, the lowering amount by each trigger is set to −2 V. Accordingly, the transmission pulse signal INPUT, while repeating potential change of rising by 3 V and falling by 2 V with respect to each trigger, eventually makes a transition from low level (0 V) to high level (5 V) by three triggers.

On the other hand, when lowered from high level (5 V) to low level (0 V), while the raising amount by each trigger is +2 V, the lowering amount by each trigger is set to −3 V. Accordingly, the transmission pulse signal INPUT, while repeating potential change of falling by 3 V and rising by 2 V with respect to each trigger, eventually makes a transition from high level (5 V) to low level (0 V) by three triggers.

Note that, in the middle row of the present figure, intervals tr between triggers are constant, but in the bottom row of the present figure, intervals tr between triggers are changed (tr→2tr→4tr). That is, inclinations (frequency components) of the transmission pulse signal INPUT and the inverted transmission pulse signal XINPUT are each changed on the trigger-by-trigger basis.

Referring to the rising of the transmission pulse signal INPUT, the first inclination is +3V/tr, and the second inclination is ½ of the first inclination (=+3V/2tr). Further, the third inclination is ¼ of the first inclination (=+4V/4tr).

According to this setting, even in a case where the transition time of the common mode noise CMT is the same as the transition time of the transmission pulse signal INPUT and the inverted transmission pulse signal XINPUT, the difference in inclination (frequency component) between the transmission pulse signal INPUT and the inverted transmission pulse signal XINPUT makes it possible to prevent an erroneous operation of trigger detection.

Note that, regarding the periods during which pulse edges of the reception pulse signal OUTPUT and the inverted reception pulse signal XOUTPUT can each be detected, it is clear that the periods are longer in the middle row than in the top row, and are even longer in the bottom row.

Next, regarding trigger setting with constant trigger intervals, two different setting examples will be presented and discussed.

To begin with, in a first setting example, the raising amount by each trigger is set to +2 V, the lowering amount by each trigger is set to −1 V, and the trigger intervals are set to 30 ns. In this case, the transmission pulse signal INPUT is triggered four times over a period of 90 ns.

At this time, the potential change of the common mode noise CMT is 150V/90 ns (=1.66 V/ns). Thus, with respect to the raising amount (+2 V) by each trigger, a difference of 0.33 V remains as an effective portion of the transmission pulse signal INPUT. As a result, a trigger pulse of about 26 mV is generated in the reception pulse signal OUTPUT, and this is transmitted to the next stage.

In this manner, in a case where a difference between the raising amount and the lowering amount by each trigger (=a potential change amount by each trigger) is set to be comparatively large, the number of triggers until the transmission pulse signal INPUT makes a transition from low level (0 V) to high level (5 V) is reduced. Thus, to deal with a case where the potential of the common mode noise CMT changes gradually, sufficient trigger intervals need to be secured. As a result, it takes a longer time for the transmission of a plurality of triggers to be completed. Further, it is necessary for the trigger intervals to be set with higher accuracy.

Next, in a second setting example, the raising amount by each trigger is set to +4 V, the lowering amount by each trigger is set to −3.9 V, and the trigger intervals are set to 4 ns. In this case, the transmission pulse signal INPUT is triggered eleven times over a period of 40 ns.

At this time, the potential change of the common mode noise CMT is 150V/40 ns (=3.75 V/ns). Accordingly, with respect to the raising amount (+4 V) by each trigger, a difference of 0.25 V remains as an effective portion of the transmission pulse signal INPUT. As a result, a trigger pulse of about 20 mV is generated in the reception pulse signal OUTPUT, and this is transmitted to the next stage.

In this manner, in a case where the difference between the raising amount and the lowering amount by each trigger (=a potential change amount by each trigger) is set to be comparatively small, the number of triggers until the transmission pulse signal INPUT makes a transition from low level (0 V) to high level (5 V) is increased. Thus, as compared with the first setting example described previously, the trigger intervals can be made shorter, and thus it takes a shorter time for the transmission of a plurality of triggers to be completed. However, since the difference between the raising amount and the lowering amount by each trigger is small, it is necessary to pay attention to avoid erroneous detection of unintentional logic inversion of the transmission pulse signal INPUT.

### Third Embodiment

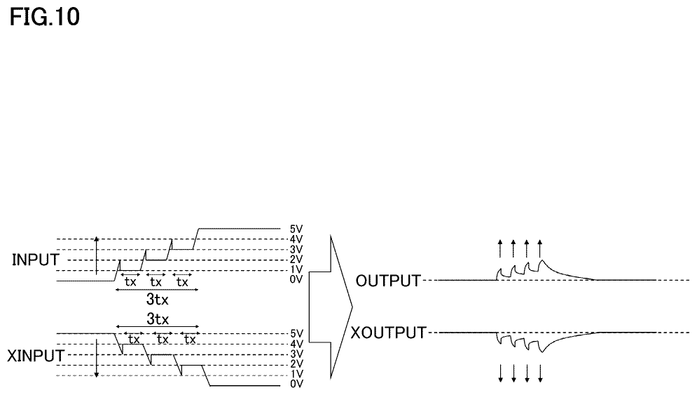

FIG. 10 is a diagram illustrating a third embodiment for enhancing common mode transient immunity (CMTI). Note that, on a left side of the present figure, a transmission pulse signal INPUT and an inverted transmission pulse signal XINPUT of the third embodiment are depicted, and on a right side of the present figure, a reception pulse signal OUTPUT and an inverted reception pulse signal XOUTPUT of the third embodiment are depicted.

In the third embodiment, as in the second embodiment (FIG. 9) described previously, during a gradual logic-level transition of each of the transmission pulse signal INPUT and the inverted transmission pulse signal XINPUT, the transmission pulse signal INPUT and the inverted transmission pulse signal XINPUT are each triggered a plurality of times such that the transmission pulse signal INPUT and the inverted transmission pulse signal XINPUT are each repeatedly raised and lowered.

In particular, in the third embodiment, following the first setting example described previously, the raising amount by each trigger is set to +2 V, the lowering amount by each trigger is set to −1 V, and the trigger intervals are set to 30 ns. Thus, the transmission pulse signal INPUT and the inverted transmission pulse signal XINPUT are each triggered four times over a period of 90 ns (=3tx). Note that the transmission pulse signal INPUT and the inverted transmission pulse signal XINPUT each have a stepwise waveform as illustrated in the present figure.

According to this setting, as previously described, potential changes of each of the reception pulse signal OUTPUT and the inverted reception pulse signal XOUTPUT accumulate. This makes it possible to enhance the level of trigger detection in a pseudo manner.

### Pulse Transmission Circuit

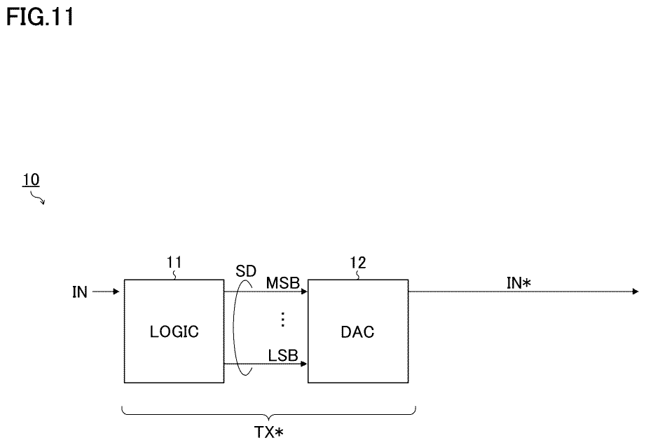

FIG. 11 is a diagram illustrating a configuration example of the pulse transmission circuit TX. The pulse transmission circuit TX* (*=1, 2, 3, 4, for example) of the present configuration example includes a logic 11 and a DAC (digital-t0-analog converter) 12.

The logic 11, on receiving the input pulse signal IN, generates a digital signal SD of n bits (n=5, for example).

The DAC 12 sets an analog value of a transmission pulse signal IN* in accordance with the digital signal SD of n bits.

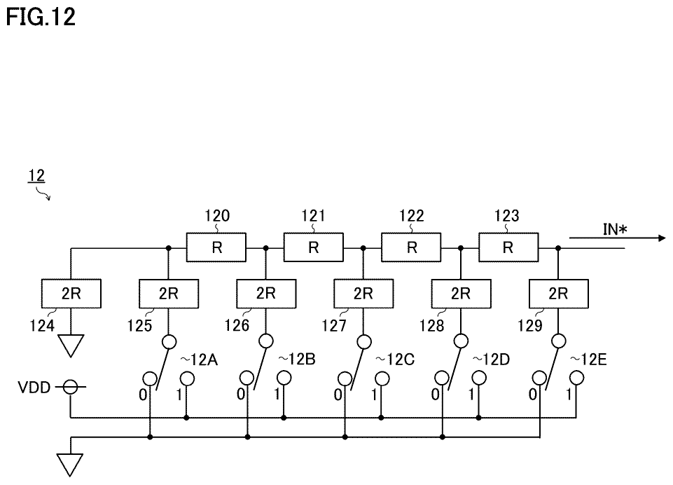

FIG. 12 is a diagram illustrating a configuration example of the DAC 12. The DAC 12 of the present configuration example is an R-2R ladder-type DAC with 5-bit resolution, and includes resistors 120 to 123 (each having a resistance R), resistors 124 to 129 (each having a resistance 2R), and selectors 12A to 12E.

A first end of the resistor 120 is connected to a first end of each of the resistors 124 and 125. A second end of the resistor 120 is connected to a first end of each of the resistors 121 and 126. A second end of the resistor 121 is connected to a first end of each of the resistors 122 and 127. A second end of the resistor 122 is connected to a first end of each of the resistors 123 and 128. A second end of the resistor 123 and a first end of the resistor 129 are connected to an output end of the transmission pulse signal IN*.

A second end of the resistor 124 is connected to a ground end. A second end of the resistor 125 is connected to a common end of the selector 12A. A second end of the resistor 126 is connected to a common end of the selector 12B. A second end of the resistor 127 is connected to a common end of the selector 12C. A second end of the resistor 128 is connected to a common end of the selector 12D. A second end of the resistor 129 is connected to a common end of the selector 12E.

A first selection end (0) of each of the selectors 12A to 12E is connected to the ground end. A second selection end (1) of each of the selectors 12A to 12E is connected to a power supply end (=an application end of a power supply voltage VDD). Note that the selectors 12A to 12E each switch, in accordance with the digital signal SD, whether to connect their common ends to their first selection ends (0) or to connect their common ends to their second selection ends (1).

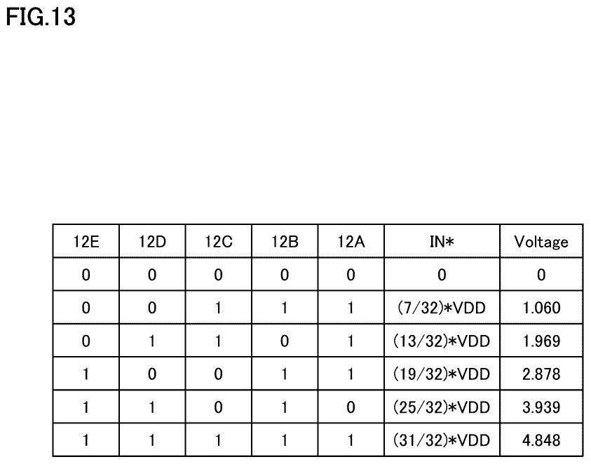

FIG. 13 is a diagram indicating relationship between selection states of the selectors 12A to 12E and DAC output values (=the transmission pulse signal IN*).

As indicated in the first row, when, in all of the selectors 12A to 12E, their common ends are respectively connected to their respective first selection ends (0), the transmission pulse signal IN* becomes 0 V. In the following description, this state will be referred to as a “first state.”

As indicated in the second row, when, in the selectors 12A to 12C, their common ends are respectively connected to their respective second selection ends (1), and in the selectors 12D and 12E, their common ends are respectively connected to their respective first selection ends (0), the transmission pulse signal IN* becomes (7/32)×VDD (IN*=1.060 V, for example). In the following description, this state will be referred to as a “second state.”

As indicated in the third row, when, in the selectors 12A, 12C, and 12D, their common ends are respectively connected to their respective second selection ends (1), and in the selectors 12B and 12E, their common ends are respectively connected to their respective first selection ends (0), the transmission pulse signal IN* becomes (13/32)×VDD (IN*=1.969 V, for example). In the following description, this state will be referred to as a “third state.”

As indicated in the fourth row, when, in the selectors 12A, 12B, and 12E, their common ends are respectively connected to their respective second selection ends (1), and in the selectors 12C and 12D, their common ends are respectively connected to their respective first selection ends (0), the transmission pulse signal IN* becomes (19/32)×VDD (IN*=2.878 V, for example). In the following description, this state will be referred to as a “fourth state.”

As indicated in the fifth row, when, in the selectors 12B, 12D, and 12E, their common ends are respectively connected to their respective second selection ends (1), and in the selectors 12A and 12C, their common ends are respectively connected to their respective first selection ends (0), the transmission pulse signal IN* becomes (25/32)×VDD (IN*=3.939 V, for example). In the following description, this state will be referred to as a “fifth state.”

As indicated in the sixth row, when, in all the selectors 12A to 12E, their common ends are respectively connected to their respective second selection ends (1), the transmission pulse signal IN* becomes (31/32)×VDD (IN*=4.848 V, for example). In the following description, this state will be referred to as a “sixth state.”

For example, to switch the transmission pulse signal INPUT (=the transmission pulse signal IN*) in a stepwise manner as illustrated in the previously referenced FIG. 10, the digital signal SD may be generated such that the selection states of the selectors 12A to 12E make transitions in the order of the first state (0 V)→the third state (2 V)→the second state (1 V, tx maintained)→the fourth state (3 V)→the third state (2 V, tx maintained)→the fifth state (4 V)→the fourth state (3 V, tx maintained)→the fifth state (5 V).

Note that the inclination of the transmission pulse signal IN* is determined by the resistances of the resistors 120 to 129 (magnitude of R) and the pad capacitance CP. In adjusting the inclination of the transmission pulse signal IN*, switching bit adjustment or the like is not necessarily required, and it is sufficient to appropriately adjust the resistances of the resistors 120 to 129.

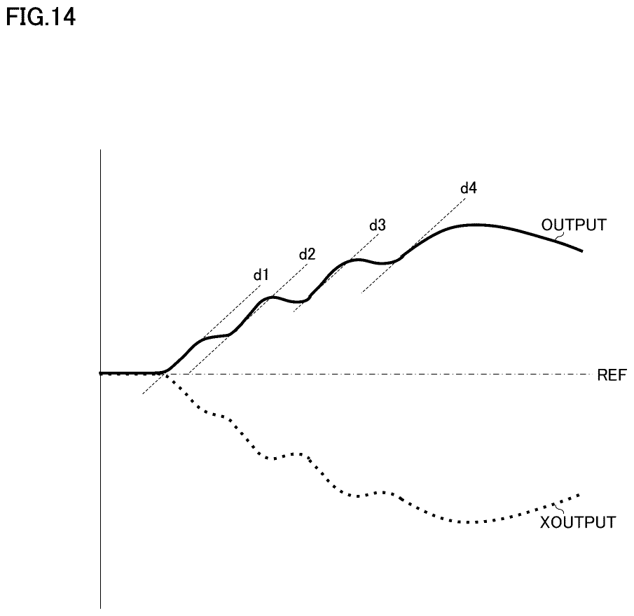

FIG. 14 is a diagram illustrating an example of the reception pulse signal OUTPUT (a solid line) and the inverted reception pulse signal XOUTPUT (a dotted line). The reception pulse signal OUTPUT is equivalent to the reception pulse signal OUT1 or OUT3 in FIG. 3. Further, the inverted reception pulse signal XOUTPUT is equivalent to the reception pulse signal OUT2 or OUT4 in FIG. 3.

By triggering the transmission pulse signal IN* a plurality of times, the reception pulse signal OUTPUT rises in a stepwise manner. Note that the resistance of the DAC 12 may be adjusted such that inclinations d1 to d4 by respective triggers are equal to each other or different from each other.

### Overview

What follows is an overview of the various embodiments disclosed above.

For example, a pulse transmission circuit disclosed herein is incorporated in a signal transmission device employing a capacitive insulation method, and configured to cause a transmission pulse signal, which is transmitted to a capacitor of a subsequent stage, to make a gradual logic-level transition when a logic level of an input pulse signal switches. (a first configuration).

The pulse transmission circuit according to the above-described first configuration may be configured to trigger the transmission pulse signal a plurality of times, while causing the transmission pulse signal to make a gradual logic-level transition, so as to repeat raising and lowering of the transmission pulse signal (a second configuration).

The pulse transmission circuit according to the above-described second configuration may be configured to set a lowering amount to be equal to or less than a raising amount by each trigger when raising the transmission pulse signal from low level to high level, and to set a raising amount to be equal to or less than a lowering amount by each trigger when lowering the transmission pulse signal from high level to low level (a third configuration).

The pulse transmission circuit according to the above-described third configuration may be configured to change an inclination of the transmission pulse signal on a trigger-by-trigger basis (a fourth configuration).

The pulse transmission circuit according to any one of the above-described second to fourth configurations may be configured to include a logic configured to generate a digital signal on receiving the input pulse signal, and a DAC configured to set an analog value of the transmission pulse signal in accordance with the digital signal (a fifth configuration).

In the pulse transmission circuit according to the above-described fifth configuration, the DAC may be configured to be of an R-2R ladder type (a sixth configuration).

Further, for example, a signal transmission device disclosed herein is configured to include the pulse transmission circuit according to any one of the above-described first to sixth configurations disposed in a primary circuit system and configured to generate the transmission pulse signal, the capacitor disposed between the primary circuit system and a secondary circuit system and configured to output a reception pulse signal corresponding to the transmission pulse signal, and a pulse reception circuit disposed in the secondary circuit system and configured to output an output pulse signal corresponding to the reception pulse signal (a seventh configuration).

The signal transmission device according to the above-described seventh configuration may be configured to seal, in a single package, a first chip configured to integrate a circuit element of the primary circuit system and a second chip configured to integrate a circuit element of the secondary circuit system (an eighth configuration).

In the signal transmission device according to the above-described eighth configuration, the pulse transmission circuit may be configured to be integrated in the first chip, and the capacitor and the pulse reception circuit may be configured to be integrated in the second chip (a ninth configuration).

Further, for example, an electronic apparatus disclosed herein may be configured to include the signal transmission device according to any one of the above-described seventh to ninth configurations, and a load configured to receive the output pulse signal (a tenth configuration).

According to the present disclosure, it is possible to enhance the common mode transient immunity of a signal transmission device employing the capacitive insulation method.

### Further Modifications

The various technical features disclosed herein may be implemented in any other manners than in the embodiments described above, and allow for any modifications made without departure from their technical ingenuity. That is, it should be understood that the above embodiments are illustrative in all respects and are not intended to limit the present disclosure, that the technological scope of the present disclosure is indicated by the claims, and that all modifications within the scope of the claims and the meaning equivalent to the claims are covered.

1. A pulse transmission circuit incorporated in a signal transmission device employing a capacitive insulation method, and configured to cause a transmission pulse signal, which is transmitted to a capacitor of a subsequent stage, to make a gradual logic-level transition when a logic level of an input pulse signal switches.

2. The pulse transmission circuit according to claim 1, configured to trigger the transmission pulse signal a plurality of times, while causing the transmission pulse signal to make a gradual logic-level transition, so as to repeat raising and lowering of the transmission pulse signal.

3. The pulse transmission circuit according to claim 2, configured to set a lowering amount to be equal to or less than a raising amount by each trigger when raising the transmission pulse signal from low level to high level, and configured to set a raising amount to be equal to or less than a lowering amount by each trigger when lowering the transmission pulse signal from high level to low level.

4. The pulse transmission circuit according to claim 3, configured to change an inclination of the transmission pulse signal on a trigger-by-trigger basis.

5. The pulse transmission circuit according to claim 2, comprising:
a logic configured to generate a digital signal on receiving the input pulse signal; and
a DAC configured to set an analog value of the transmission pulse signal in accordance with the digital signal.

6. The pulse transmission circuit according to claim 5, wherein the DAC is of an R-2R ladder type.

7. A signal transmission device, comprising:
the pulse transmission circuit according to claim 1 disposed in a primary circuit system and configured to generate the transmission pulse signal;
the capacitor disposed between the primary circuit system and a secondary circuit system and configured to output a reception pulse signal corresponding to the transmission pulse signal; and
a pulse reception circuit disposed in the secondary circuit system and configured to output an output pulse signal corresponding to the reception pulse signal.

8. The signal transmission device according to claim 7, configured to seal, in a single package,
a first chip configured to integrate a circuit element of the primary circuit system, and
a second chip configured to integrate a circuit element of the secondary circuit system.

9. The signal transmission device according to claim 8,
wherein
the pulse transmission circuit is integrated in the first chip, and
the capacitor and the pulse reception circuit are integrated in the second chip.

10. An electronic apparatus, comprising:
the signal transmission device according to claim 7; and
a load configured to receive the output pulse signal.
